(19) United States
(12) Patent Application Publication
(10) Pub. No.: US 2025/0079395 A1
(43) Pub. Date: Mar. 6, 2025

(54) METHOD OF MANUFACTURING SEMICONDUCTOR PACKAGE

(71) Applicant: Samsung Electronics Co., Ltd., Suwon-si (KR)

(72) Inventors: Sungmin MOON, Suwon-si (KR); Pyoungwan KIM, Suwon-si (KR)

(73) Assignee: Samsung Electronics Co., Ltd., Suwon-si (KR)

(21) Appl. No.: 18/815,924

(22) Filed: Aug. 27, 2024

(30) Foreign Application Priority Data
Aug. 31, 2023 (KR) 10-2023-0115606

(51) Int. Cl. H01L 23/00; H01L 21/56; H01L 21/66

(52) U.S. Cl. CPC H01L 24/83; H01L 21/565; H01L 22/12; H01L 24/27; H01L 24/81; H01L 2224/27416; H01L 2224/27436; H01L 2224/81203; H01L 2224/83039; H01L 2224/83203; H01L 2924/401

(57) ABSTRACT

A method of manufacturing a semiconductor package, the method includes preparing a first semiconductor chip including a plurality of first upper connection pads, disposing a plurality of connection bumps electrically connected to the plurality of first upper connection pads on the first semiconductor chip, forming an insulating adhesive layer at least partially covering the plurality of connection bumps on an upper surface of the first semiconductor chip, removing a plurality of regions to be removed of the insulating adhesive layer, and bonding a second semiconductor chip including a plurality of second lower connection pads on the insulating adhesive layer, wherein each of the plurality of regions to be removed is a portion of the insulating adhesive layer that at least partially overlaps a connection bump among the plurality of corresponding connection bumps in a vertical direction.

### CROSS-REFERENCE TO RELATED APPLICATION

This application is based on and claims priority under 35 U.S.C. § 119 to Korean Patent Application No. 10-2023-0115606, filed on Aug. 31, 2023, in the Korean Intellectual Property Office, the disclosure of which is incorporated by reference herein in its entirety.

### BACKGROUND

Some inventive concepts relate to a method of manufacturing a semiconductor package, and more specifically, to a method of manufacturing a semiconductor package including a plurality of vertically stacked semiconductor chips.

In accordance with the rapid development of the electronics industry and the needs of users, semiconductor packages mounted on electronic products are beneficial or required to provide high performance and include various functions. Therefore, a semiconductor package including a plurality of semiconductor chips has been proposed. Additionally, in order to reduce the size of a semiconductor package including a plurality of semiconductor chips, a semiconductor package in which a plurality of semiconductor chips are vertically stacked is being developed.

Some inventive concepts relate to a method of manufacturing a semiconductor package including an operation of selectively removing an insulating adhesive layer.

Problems to be solved by the technical spirit of some inventive concepts are not limited to the problems mentioned above, and other problems not mentioned will be clearly understood by those ordinarily skilled in the art from the following description.

According to example embodiments of some inventive concepts, a method of manufacturing a semiconductor package may include preparing a first semiconductor chip, the first semiconductor chip including a plurality of first upper connection pads; disposing a plurality of connection bumps on the first semiconductor chip, the connection bumps electrically connected to the plurality of first upper connection pads; forming an insulating adhesive layer on an upper surface of the first semiconductor chip, the adhesive layer at least partially covering the plurality of connection bumps; removing, from the insulating layer, a plurality of regions to be removed; and bonding a second semiconductor chip onto the insulating adhesive layer, the second semiconductor chip including a plurality of second lower connection pads, wherein each of the plurality of regions to be removed is a portion of the insulating adhesive layer that at least partially overlaps, a corresponding connection bump among the plurality of connection bumps in the vertical direction.

According some example embodiments of inventive concept, a method of manufacturing a semiconductor package may include disposing a plurality of connection bumps on the first semiconductor chip, the first semiconductor chip electrically connected to the plurality of first upper connection pads; forming an insulating adhesive layer on an upper surface of the first semiconductor chip, the insulating adhesive layer at least partially covering the plurality of connection bumps; measuring thicknesses of a plurality of regions to be removed, the regions to be removed being portions of the insulating adhesive layer that at least partially overlap plurality of connection bumps in a vertical direction; forming a mask on the insulating adhesive layer, the mask including a plurality of openings corresponding to each of the plurality of regions to be removed; removing the plurality of regions to be removed based on the measured thicknesses of the plurality of regions to be removed, the plurality of regions to be removed being exposed through the plurality of openings; and bonding a second semiconductor chip onto the insulating adhesive layer, the second semiconductor chip including a plurality of second lower connection pads.

According some example embodiments of inventive concepts, a method of manufacturing a semiconductor package may include stacking a plurality of semiconductor chips on the package substrate, each of the plurality of semiconductor chips including a plurality of upper connection pads and a plurality of lower connection pads; and forming a molding layer on an upper surface of the package substrate, the molding layer at least partially covering the plurality of semiconductor chips, wherein the stacking of the plurality of semiconductor chips includes disposing a plurality of connection bumps, the plurality of connection bumps electrically connected to a plurality of upper connection pads of a semiconductor chip, the semiconductor chip located at the bottom of two adjacent semiconductor chips; forming an insulating adhesive layer, the insulating adhesive layer configured to at least partially cover the plurality of connection bumps and including a plurality of regions to be removed, each of the plurality of regions to be removed at least partially overlapping ones of the plurality of connection bumps in a vertical direction; forming a mask on the insulating adhesive layer, the mask defining a plurality of openings individually corresponding to the plurality of regions to be removed; forming a plurality of recessed units by removing at least a portion of the plurality of regions to be removed, the regions to be removed being exposed through the plurality of openings; and bonding the two adjacent semiconductor chips by aligning a plurality of lower connection pads of the uppermost semiconductor chip among the two adjacent semiconductor chips to correspond to the plurality of recessed units, respectively.

### BRIEF DESCRIPTION OF THE DRAWINGS

Example embodiments will be more clearly understood from the following detailed description taken in conjunction with the accompanying drawings in which:

FIG. 1 is a diagram schematically showing a semiconductor package according to some example embodiments;

FIGS. 2 to 7 are diagrams schematically showing a method of manufacturing a semiconductor package, according to some example embodiments; and

FIG. 8 is a diagram schematically showing a semiconductor package according to some example embodiments.

### DETAILED DESCRIPTION OF THE DRAWINGS

Hereinafter, example embodiments of some inventive concepts will be described in detail with reference to the accompanying drawings. Like reference numerals are used for elements that are identical to each other, and the descriptions thereof will not be repeated.

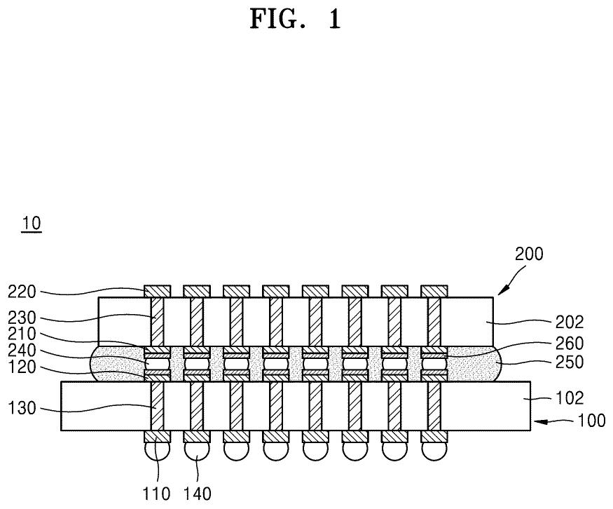

FIG. 1 is a diagram schematically showing a semiconductor package 10 according to some example embodiments.

Referring to FIG. 1, the semiconductor package 10 according to some example embodiments may include a first semiconductor chip 100, a second semiconductor chip 200, an insulating adhesive layer 250, a plurality of first connection bumps 140, and a plurality of second connection bumps 240. In FIG. 1, in the semiconductor package 10 according to some example embodiments, it is depicted that a horizontal width of the first semiconductor chip 100 is greater than a horizontal width of the second semiconductor chip 200, but the example embodiments are not limited thereto.

The first semiconductor chip 100 may include a first substrate 102, a plurality of first lower connection pads 110, a plurality of first upper connection pads 120, and a plurality of first through electrodes 130. The plurality of first connection bumps 140 may be disposed on a lower surface of the first semiconductor chip 100. Each of the plurality of first connection bumps 140 may be electrically connected to a corresponding one of plurality of first lower connection pads 110.

The second semiconductor chip 200 may include a second substrate 202, a plurality of second lower connection pads 210, a plurality of second upper connection pads 220, and a plurality of second through electrodes 230. A plurality of second connection bumps 240 may be disposed on a lower surface of the second semiconductor chip 200. Each of the plurality of second connection bumps 240 may be electrically connected to a corresponding one of the plurality of second lower connection pads 210. Additionally or alternatively, each of the plurality of second connection bumps 240 may be electrically connected to a corresponding one of first upper connection pads 120. For example, the second connection bump 240s may be electrically connected to the first upper connection pad 120 of the first semiconductor chip 100 and to the second lower connection pad 220 of the second semiconductor chip 200.

The first substrate 102 and the second substrate 202 may individually include, for example, silicon (Si). Additionally or alternatively, the first substrate 102 and the second substrate 202 may individually include, for example, a semiconductor element, such as germanium (Ge), or a compound semiconductor, such as silicon carbide (SiC), gallium arsenide (GaAs), indium arsenide (InAs), and indium phosphide (InP), but example embodiments are not limited thereto. The first substrate 102 and the second substrate 202 may each have an active surface and an inactive surface opposite to the active surface.

The first substrate 102 and the second substrate 202 may each include, for example, a plurality of various types of individual devices on the active surfaces thereof. The plurality of individual devices may include, for example, at least one of various microelectronic devices, for example, a metal-oxide-semiconductor field effect transistor (MOSFET), such as a complementary metal-insulator-semiconductor (CMOS) transistor, a system large scale integration (LSI), an imaging sensor, such as CMOS imaging sensor (CIS), a micro-electro-mechanical system (MEMS), active elements and/or passive elements, etc., but example embodiments are not limited thereto.

The first semiconductor chip 100 and the second semiconductor chip 200 may respectively include a first semiconductor device and a second semiconductor device formed by the plurality of individual devices described above. For example, the first semiconductor device may be formed on the active surface of the first substrate 102, the plurality of first lower connection pads 110 may be disposed on the active surface of the first substrate 102, and the plurality of first upper connection pads 120 may be disposed on the inactive surface of the first substrate 102. The second semiconductor device may be formed on the active surface of the second substrate 202, the plurality of second lower connection pads 210 may be disposed on the active surface of the second substrate 202, and the plurality of second upper connection pads 220 may be disposed on the inactive surface of the second substrate 202.

The plurality of first through electrodes 130 may include, for example, through silicon vias (TSVs) having a structure that penetrate the silicon of the first substrate 102. Also, the plurality of second through electrodes 230 may be TSVs having a structure that penetrates the silicon of the second substrate 202. The first through electrode 130 may connect the first lower connection pad 110 to the first upper connection pad 120 using an electrode inside the first substrate 102 to transmit an electrical signal therebetween. Also, the second through electrode 230 may transmit an electrical signal by connecting the second lower connection pad 210 to the second upper connection pad 220 using an electrode inside the second substrate 202.

The plurality of first connection bumps 140 may be respectively attached to the plurality of first lower connection pads 110 of the first semiconductor chip 100. The plurality of first connection bumps 140 may electrically connect the first semiconductor chip 100 to an external device.

The plurality of second connection bumps 240 may be respectively attached to the plurality of second lower connection pads 210 of the second semiconductor chip 200. The second connection bump 240 may be between the first upper connection pad 120 of the first semiconductor chip 100 and the second lower connection pad 210 of the second semiconductor chip 200 as to electrically connect the first semiconductor chip 100 to the second semiconductor chip 200. As a result, the first semiconductor chip 100 and the second semiconductor chip 200 may be electrically connected to each other.

The insulating adhesive layer 250 may be in contact with the plurality of second connection bumps 240. For example, the insulating adhesive layer 250 may surround or at least partially surround sidewalls of the plurality of second connection bumps 240. For example, the insulating adhesive layer 250 may be between the first semiconductor chip 100 and the second semiconductor chip 200. The insulating adhesive layer 250 may fill a space between the first semiconductor chip 100 and the second semiconductor chip 200. An upper surface of the insulating adhesive layer 250 may be at the same or substantially the same vertical level as a lower surface of the second semiconductor chip 200, and a lower surface of the insulating adhesive layer 250 may be at the same or substantially the same vertical level as an upper surface of the first semiconductor chip 100. The insulating adhesive layer 250 may include, for example, a non-conductive film (NCF). The insulating adhesive layer 250 may be, for example, manufactured as a laminated film and formed on the first semiconductor chip 100, but example embodiments are not limited thereto.

An intermetallic compound 260 may be formed between the second connection bump 240 and the first upper connection pad 120. Additionally or alternatively, the intermetallic compound 260 may be formed between the second connection bump 240 and the second lower connection pad 210. The intermetallic compound 260 may be formed, e.g., by bonding the second connection bump 240 to the first upper connection pad 120 and the second lower connection pad 210.

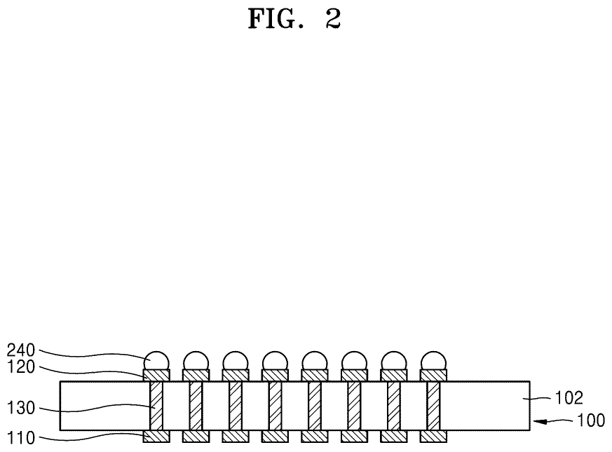

FIGS. 2 to 7 are diagrams schematically showing a method of manufacturing a semiconductor package, according to some example embodiments.

Referring to FIG. 2, a method of manufacturing a semiconductor package, according to some example embodiments, may include preparing a first semiconductor chip 100. The first semiconductor chip 100 may include a plurality of first lower connection pads 110, a plurality of first upper connection pads 120, and a plurality of first through electrodes 130. Additionally or alternatively, a plurality of second connection bumps 240 may be formed on the first semiconductor chip 100. At this time, each of the plurality of second connection bumps 240 may be formed to be electrically connected to corresponding ones of the plurality of first upper connection pads 120 of the first semiconductor chip 100.

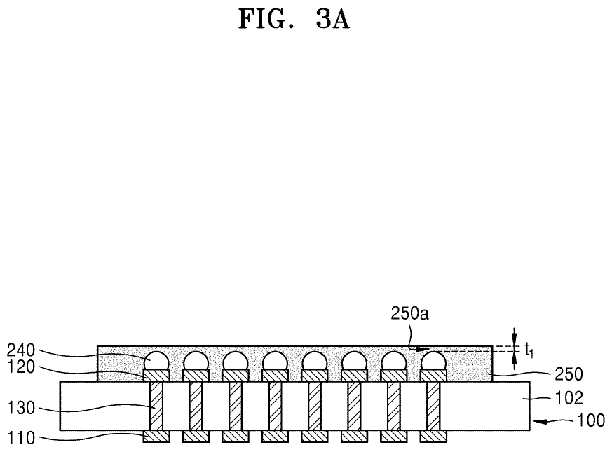

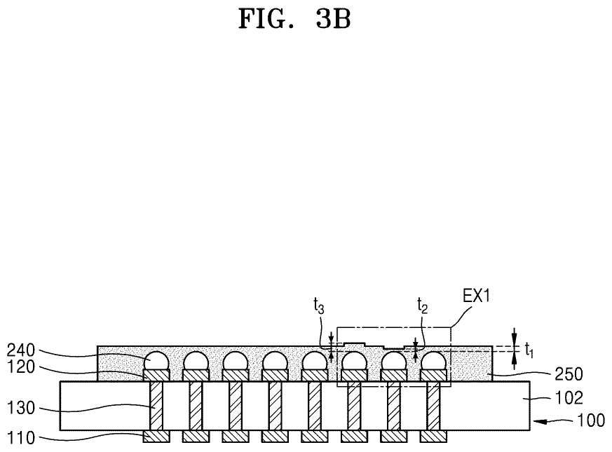

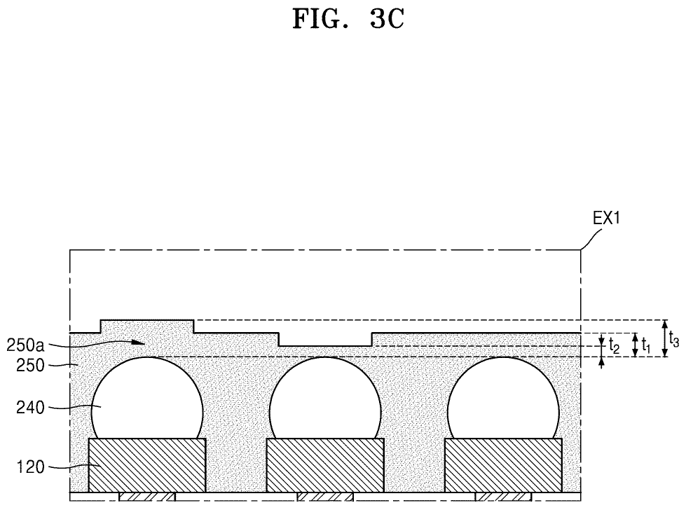

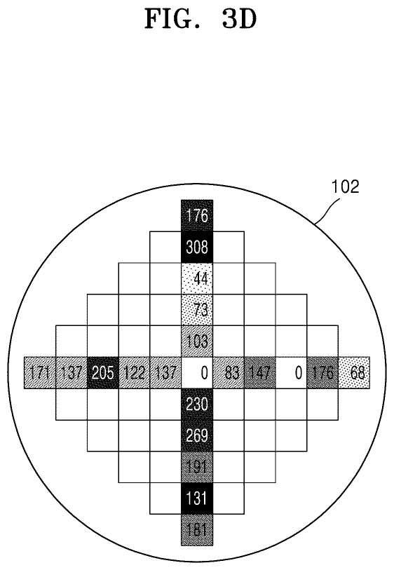

FIG. 3A is a diagram showing that an upper surface of the insulating adhesive layer 250 is formed to be flat or substantially flat. FIG. 3B is a diagram showing that the upper surface of the insulating adhesive layer 250 is not flat or substantially flat. FIG. 3C is an enlarged view of a portion EX1 of FIG. 3B. FIG. 3D is an image showing a thickness distribution of the insulating adhesive layer 250 formed on the first substrate 102.

Referring to FIG. 3A, the insulating adhesive layer 250 may be formed on an upper surface of the first semiconductor chip 100 to cover or at least partially cover the plurality of second connection bumps 240. The upper surface of the insulating adhesive layer 250 may be formed to be flat. The insulating adhesive layer 250 may include, for example, an NCF. The insulating adhesive layer 250 may, for example, be manufactured as a laminated film and attached to the upper surface of the first semiconductor chip 100. However, example embodiments of the method of forming the insulating adhesive layer 250 are not limited thereto, and the insulating adhesive layer 250 in a liquid state may be formed, for example, on the upper surface of the first semiconductor chip 100 using a spin coating method.

The insulating adhesive layer 250 may include a plurality of regions 250a to be removed. At this time, the plurality of regions 250a to be removed refers to portions of the insulating adhesive layer 250 that overlap or at least partially overlap the corresponding plurality of second connection bumps 240 in a vertical direction. At this time, the vertical direction refers to a direction perpendicular to the upper surface of the first semiconductor chip 100. Each of the plurality of regions 250a to be removed may be formed to have a predetermined thickness t₁ in the vertical direction. The insulating adhesive layer 250 may be formed to have a uniform thickness. For example, the vertical thickness t₁ of each of the plurality of regions 250a to be removed may be, for example, the same, but example embodiments are not limited thereto. The thickness t₁ of the plurality of regions 250a to be removed may be within about several hundred nm. For example, the thickness t₁ of the plurality of regions 250a to be removed may be, for example, within about 300 nm, but example embodiments are not limited thereto.

Referring to FIGS. 3B to 3D, the plurality of regions 250a to be removed may be formed to have first to third thicknesses t₁, t₂, and t₃ in the vertical direction different from each other. For example, the second thickness t₂ may be less than the first thickness t₁ and the third thickness t₃ may be greater than the first thickness t₁. At this time, the plurality of regions 250a to be removed refers to portions of the insulating adhesive layer 250 that overlap the corresponding plurality of second connection bumps 240 in the vertical direction. At this time, the vertical direction refers to a direction perpendicular to the upper surface of the first semiconductor chip 100. At this time, the first to third thicknesses t₁, t₂, and t₃ of the plurality of regions 250a to be removed may be within about several hundreds of nm. For example, the first to third thicknesses t₁, t₂, and t₃ of the plurality of regions 250a to be removed may be formed to be within 300 about nm, but example embodiments are not limited thereto.

Referring to FIG. 3D, the method of manufacturing a semiconductor package, according to an some example embodiments, may further include measuring the thickness of each of a plurality of regions 250a to be removed (see FIG. 3C). The operation of measuring the thickness of each of the plurality of regions 250a to be removed may measure a thickness distribution of the plurality of regions 250a to be removed. For example, FIG. 3D shows the thicknesses of the region 250a to be removed in nm unit for each specific location when the insulating adhesive layer 250 is formed on the first substrate 102 of the first semiconductor chip 100. At this time, the difference between the maximum and minimum thicknesses of the regions 250a to be removed may be about 300 nm, but example embodiments are not limited thereto.

In the conventional art, in a process of forming an insulating adhesive layer, a thickness deviation may occur in each of regions to be removed that overlap a plurality of connection bumps in the vertical direction. Accordingly, there may be a problem of poor bonding between the connection bump and a pad due to the thickness deviation of the region to be removed. For example, there may be a problem of bonding defects such as non-wet or de-wet defects. In addition, when a region to be removed is removed by using plasma after forming an insulating adhesive layer to mitigate or solve the bonding defect, there may be a problem in that the insulating adhesive layer is pre-hardened, and thus, a bonding defect occurs. Also, during removal or regions to be removed, problems such as damage to the insulating adhesive layer may occur.

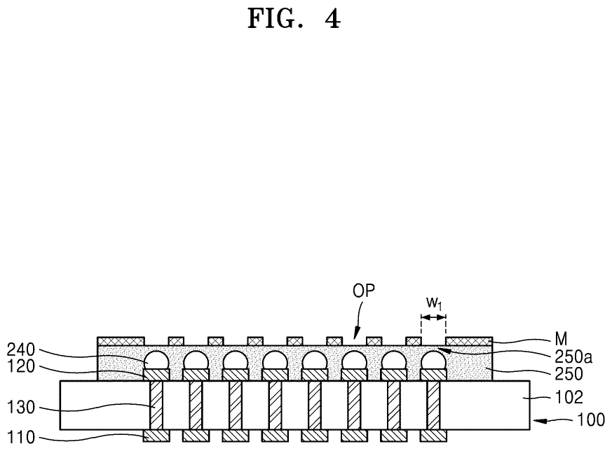

Referring to FIG. 4, a mask M may be formed on the insulating adhesive layer 250. The mask M may define a plurality of openings OP individually corresponding to the plurality of regions 250a to be removed. At this time, the mask M may include SUS (standard unit size), but example embodiments are not limited thereto. A horizontal width W₁ of each of the plurality of openings OP may be the same or substantially the same as a horizontal width of the first upper connection pads 120 but is not limited thereto. For example, the horizontal width W₁ of the plurality of openings OP may be about 25 μm, but example embodiments are not limited thereto.

In some example embodiments, the horizontal width W₁ of the plurality of openings OP may be greater than, substantially the same as, or equal to a horizontal width of the second connection bumps 240. However, example embodiments are not limited thereto, and the horizontal width W of the plurality of openings OP may be less or substantially less than the horizontal width of the second connection bumps 240. Also, from a plan view, a shape of the plurality of openings OP may be the same, similar to or substantially similar to a shape of the second connection bump 240. For example, from a plan view, the shape of the plurality of openings OP may be circular. However, example embodiments are not limited thereto, the shape of the plurality of openings OP may be variously designed as needed.

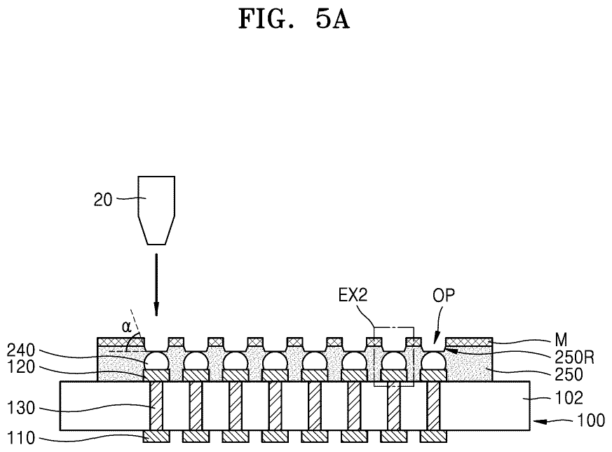

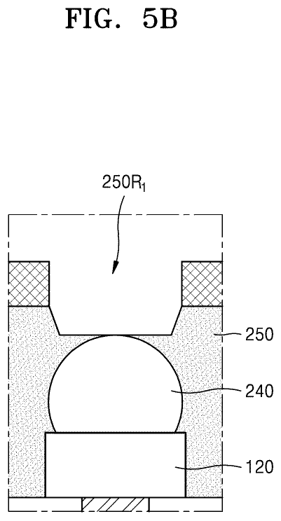

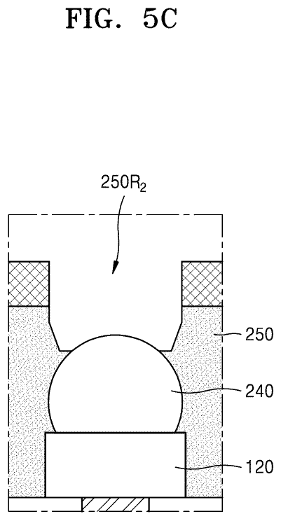

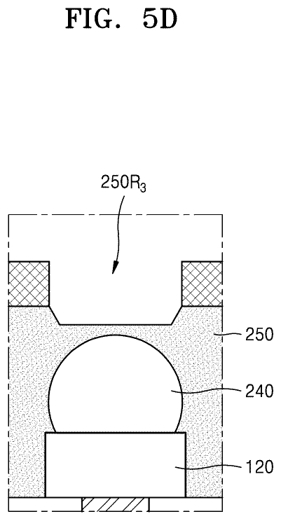

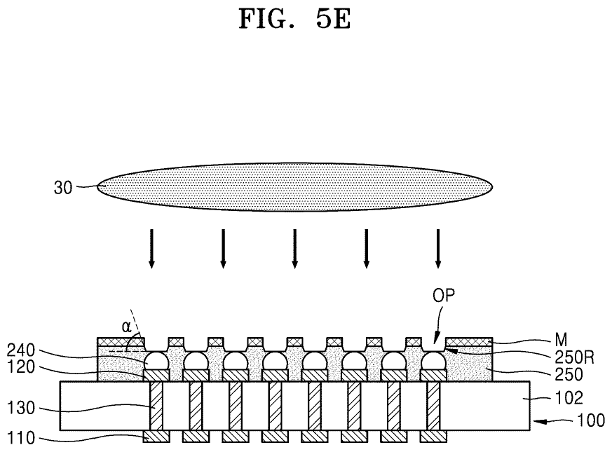

Referring to FIG. 5A, the method of manufacturing a semiconductor package, according to some example embodiments, may include selectively removing the insulating adhesive layer 250. In more detail, a plurality of regions 250a to be removed (see FIG. 4) of the insulating adhesive layer 250 may be removed. A plurality of recessed units 250R may be formed by removing at least some of the plurality of regions 250a to be removed. The plurality of recessed units 250R may be formed by removing at least some of the plurality of regions 250a to be removed that are exposed through the plurality of openings OP of the mask M. By using the mask M, only the plurality of regions 250a to be removed may be selectively removed from the insulating adhesive layer 250.

Some portions of the insulating adhesive layer 250 may be removed in the vertical direction to form a plurality of recessed units 250R. At this time, each of the plurality of recessed units 250R may be formed to have a predetermined angle ‘a’ with an upper surface of the insulating adhesive layer 250. At this time, the predetermined angle ‘a’ may be about 90° or less. For example, the plurality of recessed units 250R may be formed to have, for example, a uniform horizontal width in a direction perpendicular to the upper surface of the insulating adhesive layer 250. Additionally or alternatively, ones of the plurality of recessed units 250R may have, for example, a tapered shape in which a width of the tapered shape is reduced as a distance from the upper surface of the insulating adhesive layer 250 increases.

In some example embodiments, the plurality of recessed units 250R may be formed, for example, by using a laser drilling method. The plurality of recessed units 250R may be formed by removing the plurality of regions 250a to be removed that are exposed through the plurality of openings OP by using a laser device 20. At this time, the laser drilling method may be performed using a line scan method. Because the regions 250a to be removed may be removed using the openings OP of the mask M, the plurality of regions 250a to be removed may be removed by using, for example, a line scan method. A line scan speed may be hundreds of mm/s but is not limited thereto. In the method of manufacturing a semiconductor package according to some example embodiments, because a line scan method is used, the process time may be reduced or minimized even when the mask M is used.

In the method of manufacturing a semiconductor package according to some example embodiments, a plurality of recessed units 250R may be formed by removing at least a portion of the plurality of regions 250a to be removed, and accordingly, there may be an effect of improving bonding defects between the second connection bump 240 and the second lower connection pad 210. By removing at least a portion of the regions 250a to be removed, at least a portion of the second connection bumps 240 may be exposed. By exposing the second connection bumps 240, the second connection bump 240 may be effectively bonded to the second lower connection pad 210.

In some example embodiments, even if ones of the plurality of regions 250a to be removed are formed to have different thicknesses, such as the first to third thicknesses t₁, t₂, and t₃ in the vertical direction (refer to FIGS. 3B and 3C), the plurality of recessed units 250R may be formed to have the same depth. By adjusting an output intensity of the laser device 20, the number of drilling times, the process time, the size of the opening OP of the mask M, etc., the removal amount of each of the plurality of regions 250a to be removed may be adjusted differently. By adjusting the removal amount of each of the plurality of regions 250a to be removed differently, the plurality of recessed units 250R may be formed to have the same depth, but example embodiments are not limited thereto.

For example, when the thickness of the region 250a to be removed is thick (e.g., t₃ in FIG. 3C), a relatively large amount of the region 250a to be removed may be removed to form the recessed unit 250R. Also, when the thickness of the region 250a to be removed is relatively thin (for example, t₂ in FIG. 3C), the recessed unit 250R may be formed by removing a relatively small amount of the region 250a to be removed. By forming the plurality of recessed units 250R to have the same depth, the corresponding second connection bumps 240 may be equally exposed. By exposing the second connection bumps 240 equally, a bonding process for bonding the plurality of second connection bumps 240 to the corresponding plurality of second lower connection pads 210 may be effectively performed.

In some example embodiments, in the method of manufacturing a semiconductor package according to some example embodiments, the removal amount of the region 250a to be removed may be adjusted by considering the thickness of the region 250a to be removed. For example, the removal amount of each of the plurality of regions 250a to be removed may be adjusted using results of cross-sectional analysis using, for example, a scanning electron microscopy (SEM) device, etc. Using the cross-sectional analysis results, at least a portion of the region 250a to be removed may be removed so that at least a portion of the second connection bump 240 is exposed. For example, a thickness of the region 250a to be removed may be about 500 nm or less, but example embodiments are not limited thereto. In addition, the removal amount of each of the plurality of regions 250a to be removed may be adjusted differently using the cross-sectional analysis results, but example embodiments are not limited thereto. For example, the removal amount of the plurality of regions 250a may be adjusted to be equal to each other.

In some example embodiments, in the method of manufacturing a semiconductor package according to some example embodiment, the removal amount of each of the plurality of regions 250a may be equally adjusted by considering a thickness distribution of the plurality of regions 250a. At least a portion of the regions 250a to be removed may be removed by using the thickness distribution of the plurality of regions 250a to be removed measured as shown in in FIG. 3D. The regions 250a to be removed may be removed by using the difference between maximum and minimum thicknesses of the plurality of regions 250a to be removed. For example, as shown in FIG. 3D, when the difference between the maximum and minimum thicknesses of the regions 250a to be removed is about 300 nm, each of the plurality of regions 250a to be removed may be removed by more than about 300 nm in the vertical direction. For example, each of the plurality of regions 250a to be removed may be removed in a range from about 300 nm to about 500 nm in the vertical direction, but example embodiments are not limited thereto.

By removing each of the regions 250a to be removed by as much as the difference between the maximum and minimum thicknesses of the plurality of regions 250a, a process of bonding the plurality of second connection bumps 240 and the plurality of second lower connection pads 210 corresponding thereto may be effectively performed.

Referring to FIGS. 5B to 5D, when the plurality of regions 250a to be removed are formed to have different thicknesses, For example, the first to third thicknesses t₁, t₂, and t₃, in the vertical direction (refer to FIGS. 3B and 3C), a plurality of recessed units, for example, first to third recessed units 250R₁, 250R₂, and 250R₃ may be formed to have different depths. Even if the plurality of regions 250a have different thicknesses, For example, the first to third thicknesses t₁, t₂, and t₃, in the vertical direction, the regions to be removed 250a may be removed equally. For example, the region 250a to be removed may be removed by as much as the difference between the maximum and minimum thicknesses of the plurality of regions 250a to be removed. At this time, at least a portion of the second connection bump 240 may be exposed. However, the example embodiments are not limited thereto, and some of the second connection bumps 240 may not be exposed.

In some example embodiments, referring to FIGS. 3C and 5B together, the region 250a to be removed having the first thickness t₁ may be removed to form the first recessed unit 250R₁. For example, a lower surface of the first recessed unit 250R₁ may be formed to be the same as an upper surface of the second connection bump 240, but example embodiments are not limited thereto. Even if the upper surface of the second connection bump 240 is not exposed by the first recessed unit 250R₁, by removing a portion of the insulating adhesive layer 250, there is an effect of facilitating bonding of the second connection bump 240 to the second lower connection pad 210.

In some example embodiments, referring to FIGS. 3C and 5C together, the region 250a to be removed having the second thickness t₂ may be removed to form the second recessed unit 250R₂. A lower surface of the second recessed unit 250R₂ may be formed at a vertical level lower than the upper surface of the second connection bump 240. By exposing the upper surface of the second connection bump 240 by the second recessed unit 250R₂, there is an effect of facilitating bonding of the second connection bump 240 to the second lower connection pad 210.

In some example embodiments, referring to FIGS. 3C and 5D together, the third recessed unit 250R₃ may be formed by removing the region 250a to be removed having the third thickness t₃. A lower surface of the third recessed unit 250R₃ may be formed at a vertical level higher than the upper surface of the second connection bump 240. Even if the upper surface of the second connection bump 240 is not exposed by the third recessed unit 250R₃, by removing a portion of the insulating adhesive layer 250, there is an effect of facilitating bonding of the second connection bump 240 to the second lower connection pad 210.

In the method of manufacturing a semiconductor package according to some example embodiments, by using the mask M, only the region 250a to be removed may be selectively removed from the insulating adhesive layer 250. Because the insulating adhesive layer 250 is selectively removed, there is an effect of reducing or preventing pre-hardening of the insulating adhesive layer 250 compared to removing the entire region of the insulating adhesive layer 250. In addition, there is an effect of reducing or preventing bonding defects such as de-wet or non-wet caused by overexposure or underexposure of the second connection bump 240. In addition, there is an effect of reducing or preventing a side effect of edge unfill defect in a process of bonding the first semiconductor chip 100 and the second semiconductor chip 200, but benefits of selecting removing the insulating adhesive layer 250 are not limited thereto.

In the method of manufacturing a semiconductor package according to some example embodiments, by removing at least a portion of the region 250a to be removed by using the mask M, there is an effect of reducing or preventing formation of NCF fillets due to excessive bonding force when bonding the first semiconductor chip 100 to the second semiconductor chip 200. Also, because the insulating adhesive layer 250 is removed to a minimum or minor degree, the insulating adhesive layer 250 may move during the bonding process of the first semiconductor chip 100 to the second semiconductor chip 200. As the insulating adhesive layer 250 moves, an oxide film, for example, of the exposed second connection bump 240 may be removed. Accordingly, the reliability of the semiconductor package may be improved.

Referring to FIG. 5E, in the method of manufacturing a semiconductor package according to some example embodiments, the plurality of regions 250a to be removed (refer to FIG. 4) of the insulating adhesive layer 250 may be removed by using plasma 30. In the description with reference to FIG. 5E, descriptions common to the descriptions made with reference to FIGS. 5A to 5D will be omitted.

The plurality of recessed units 250R may be formed by removing at least a portion of the plurality of regions 250a to be removed. A plurality of recessed units 250R may be formed by removing at least a portion of the plurality of regions 250a to be removed that are exposed through the plurality of openings OP of the mask M. By using the mask M, a plurality of regions 250a to be removed may be selectively removed from the insulating adhesive layer 250.

Some portions of the insulating adhesive layer 250 may be removed in the vertical direction to form the plurality of recessed units 250R. At this time, each of the plurality of recessed units 250R may be formed to have a predetermined angle a with the upper surface of the insulating adhesive layer 250. At this time, the predetermined angle ‘a’ may be, for example, about 90° or less. For example, the plurality of recessed units 250R may be formed to have a uniform horizontal width in a direction perpendicular to the upper surface of the insulating adhesive layer 250. Additionally or alternatively, ones of the plurality of recessed units 250R may have a tapered shape in which a width of the tapered shape narrows as a distance from the upper surface of the insulating adhesive layer 250 increases, but example embodiments are not limited thereto.

In some example embodiments, the plurality of recessed units 250R may be formed using plasma 30. A plurality of regions 250a to be removed that are exposed through the plurality of openings OP may be removed using the plasma 30 to form a plurality of recessed units 250R. At this time, O₂, CF₄, etc., for example, may be used, for example, as a plasma source gas, but example embodiments are not limited thereto. Because the regions 250a to be removed may be removed using the openings OP defined by the mask M, there may be an effect of reducing or minimizing overall damage to the insulating adhesive layer 250. Because only the regions 250a to be removed may be selectively removed from the insulating adhesive layer 250 using the mask M, there is an effect of reducing or minimizing side effects caused by pre-curing of the insulating adhesive layer 250.

In the method of manufacturing a semiconductor package according to some example embodiments, because the plurality of recessed units 250R are formed by removing at least a portion of the plurality of regions 250a to be removed, there is an effect of improving bonding defects between the second connection bump 240 and the second lower connection pad 210. By removing at least a portion of the regions 250a to be removed, the second connection bumps 240 may be effectively bonded to the second lower connection pads 210.

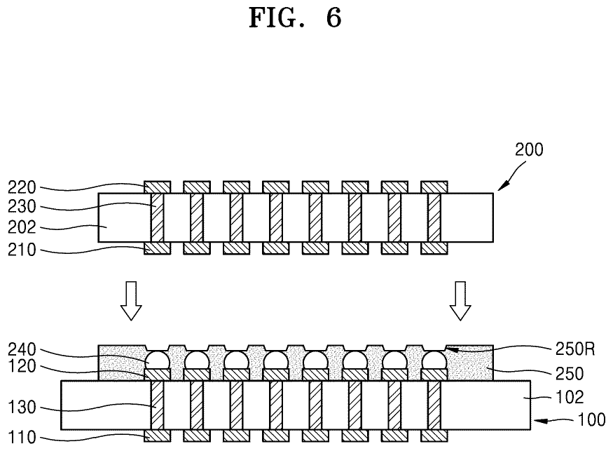

Referring to FIG. 6, the plurality of second lower connection pads 210 of the second semiconductor chip 200 may be, for example, individually aligned with corresponding ones of the plurality of second connection bumps 240. The plurality of second lower connection pads 210 may be aligned with the plurality of recessed units 250R formed by removing the plurality of regions 250a to be removed.

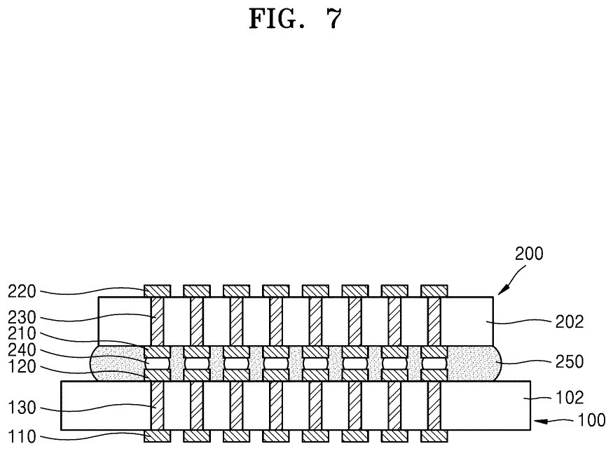

Referring to FIG. 7, the second semiconductor chip 200 may be bonded on the insulating adhesive layer 250. The plurality of second lower connection pads 210 may be bonded to the plurality of second connection bumps 240. The second semiconductor chip 200 may be electrically connected to the first semiconductor chip 100. Additionally or alternatively, in a process of bonding the second semiconductor chip 200 to the first semiconductor chip 100, a thermal compression process in which, for example, a predetermined amount of heat and pressure is applied to the insulating adhesive layer 250 may be performed. When predetermined amount of heat and pressure is applied to the insulating adhesive layer 250, a portion of the insulating adhesive layer 250 may move laterally.

Referring again to FIG. 1, the intermetallic compound 260 may be, for example, formed between the second connection bump 240 and the first upper connection pad 120 according to, for example, the thermal compression process described with reference to FIG. 6 above. Additionally or alternatively, the intermetallic compound 260 may be formed between the second connection bump 240 and the second lower connection pad 210. The intermetallic compound 260 may be formed by bonding the second connection bump 240 to the first upper connection pad 120 and the second lower connection pad 210. Additionally or alternatively, a plurality of first connection bumps 140 may be formed on the plurality of first lower connection pads 110.

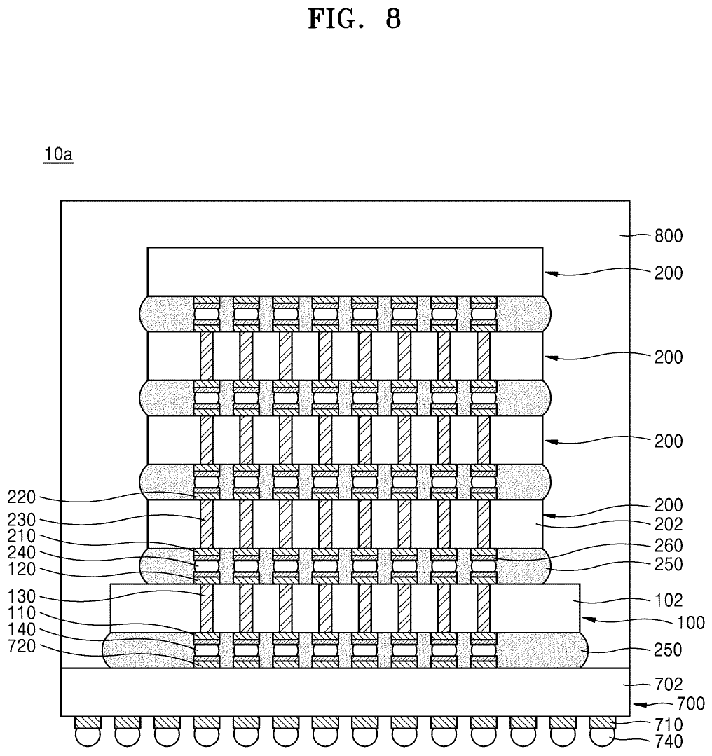

FIG. 8 is a diagram schematically showing a semiconductor package 10a according to some example embodiments.

The semiconductor package 10a according to some example embodiments may include a first semiconductor chip 100, a plurality of second semiconductor chips 200, a plurality of insulating adhesive layers 250, and a package substrate 700.

The semiconductor package 10a may include one first semiconductor chip 100 and a plurality of second semiconductor chips 200. The plurality of second semiconductor chips 200 may be stacked on each other in a vertical direction. In some example embodiments, the first semiconductor chip 100 may not include a memory cell. The first semiconductor chip 100 may include, for example, at least one of a test logic circuit, such as a serial-parallel conversion circuit, design for test (DFT), a joint test action group (JTAG), a memory built-in self-test (MBIST), and a signal interface circuit, such as PHY, but example embodiments are not limited thereto. The second semiconductor chip 200 may include, for example, at least one memory cell, but example embodiments are not limited thereto. For example, the first semiconductor chip 100 may include a buffer chip for controlling the second semiconductor chip 200, but example embodiments are not limited thereto.

The second semiconductor chip 200 may be or include a volatile memory, such as dynamic random-access memory (DRAM) and static random access memory (SRAM) or a non-volatile memory, such as phase-change random access memory (PRAM), magneto-resistive random access memory (MRAM), ferroelectric random access memory (FeRAM), or resistive random access memory (RRAM).

In some example embodiments, the first semiconductor chip 100 and the plurality of second semiconductor chips 200 may form a high bandwidth memory (HBM). For example, the first semiconductor chip 100 may be a buffer chip for controlling HBM DRAM, and the plurality of second semiconductor chips 200 may be memory cell chips having HBM DRAM cells controlled by the first semiconductor chip 100. The first semiconductor chip 100 may include and/or be referred to as a buffer chip, a master chip, or an HBM control die, and the plurality of second semiconductor chips 200 may be referred to as a memory chip, a slave chip, a DRAM dice, or a DRAM slice. The first semiconductor chip 100 and the plurality of second semiconductor chips 200 stacked on the first semiconductor chip 100 may be collectively referred to as an HBM DRAM device or an HBM DRAM chip.

In FIG. 8, it is depicted that one semiconductor package 10a includes four second semiconductor chips 200, but one semiconductor package 10a may include, for example, three or less or five or more second semiconductor chips 200. For example, one semiconductor package 10a may include eight, twelve, or sixteen second semiconductor chips 200, but example embodiments are not limited thereto.

In some example embodiments, among the plurality of second semiconductor chips 200, the second semiconductor chip 200 located at the top and farthest from the first semiconductor chip 100 may not, for example, include second upper connection pads 220 and the second through electrode 230. Additionally, a thickness of the second semiconductor chip 200 located at the top and farthest from the first semiconductor chip 100 may have a thickness greater or substantially greater than a thickness of the other second semiconductor chips 200, but example embodiments are not limited thereto.

The insulating adhesive layer 250 may be in contact with the plurality of first connection bumps 140. That is, the insulating adhesive layer 250 may surround, for example, at least partially surround, sidewalls of the plurality of first connection bumps 140. That is, the insulating adhesive layer 250 may be between the first semiconductor chip 100 and the package substrate 700. The insulating adhesive layer 250 may fill or at least partially fill a space between the first semiconductor chip 100 and the package substrate 700.

The insulating adhesive layer 250 may be in contact with the plurality of second connection bumps 240. That is, the insulating adhesive layer 250 may surround, for example, at least partially surround, sidewalls of the plurality of second connection bumps 240. For example, the insulating adhesive layer 250 may be between the first semiconductor chip 100 and the second semiconductor chip 200. The insulating adhesive layer 250 may fill or at least partially fill a space between the first semiconductor chip 100 and the second semiconductor chip 200. Additionally or alternatively, the insulating adhesive layer 250 may be between the plurality of second semiconductor chips 200. The insulating adhesive layer 250 may fill or at least partially fill a space between two adjacent second semiconductor chips 200, but example embodiments are not limited thereto.

The insulating adhesive layer 250 may be, for example, a non-conductive film (NCF). The insulating adhesive layer 250 may be, for example, manufactured as a laminated film and formed on the package substrate 700, the first semiconductor chip 100, and the second semiconductor chip 200, but example embodiments are not limited thereto.

An intermetallic compound 260 may be formed between the first connection bump 140 and a top pad 720 of the package substrate 700. Additionally or alternatively, the intermetallic compound 260 may be, for example, formed between the first connection bump 140 and the first lower connection pad 110. The intermetallic compound 260 may be formed by bonding the first connection bump 140 to the package substrate upper pad 720 and the first lower connection pad 110.

The intermetallic compound 260 may be formed between the second connection bump 240 and the first upper connection pad 120. Additionally or alternatively, the intermetallic compound 260 may be formed between the second connection bump 240 and the second lower connection pad 210. The intermetallic compound 260 may be formed by bonding the second connection bump 240 to the first upper connection pad 120 and the second lower connection pad 210.

In some example embodiments, the package substrate 700 may be disposed on a lower surface of the first connection bump 140 facing a lower surface of the first semiconductor chip 100. That is, the first semiconductor chip 100 and a plurality of second semiconductor chips 200 may be sequentially stacked on the package substrate 700.

The package substrate 700 may include a base board layer 702, a plurality of package substrate upper pads 720 and a plurality of package substrate lower pads 710 disposed respectively on upper and lower surfaces of the base board layer 702. The package substrate 700 may include a plurality of first wiring paths (not shown) that electrically connect the plurality of package substrate upper pads 720 to the plurality of package substrate lower pads 710 through the base board layer 702. In some example embodiments, the package substrate 700 may be or include a printed circuit board (PCB). For example, the package substrate 700 may be or include a multi-layer printed circuit board. In another example embodiment, the package substrate 700 may include an interposer, but example embodiments are not limited thereto.

In some example embodiments, the semiconductor package 10a may further include a molding layer 800 surrounding or at least partially surrounding the plurality of second semiconductor chips 200 and the insulating adhesive layer 250 on the first semiconductor chip 100. The molding layer 800 may include, for example, an epoxy mold compound (EMC), but example embodiments are not limited thereto. The molding layer 800 may cover or at least partially over side surfaces of the plurality of second semiconductor chips 200, side surfaces of the insulating adhesive layer 250, and an upper surface of the uppermost second semiconductor chip 200 among the plurality of second semiconductor chips 200.

In another example embodiment, the semiconductor package 10a may be a 2.5-dimensional semiconductor package or a three-dimensional semiconductor package. The three-dimensional semiconductor package may be formed by vertically stacking multiple layers of identical or different semiconductor chips, thereby reducing a distance between the semiconductor chips. The semiconductor chips each have penetrating electrodes, which may shorten the time to transmit data to other semiconductor chips. In the three-dimensional semiconductor package, various types of semiconductor chips may be, for example, freely arranged, as to increase the speed of data processing between semiconductor chips, but example embodiments are not limited thereto.

For example, a semiconductor package may include a plurality of semiconductor chips, and the semiconductor package may be a system-in-package in which a plurality of semiconductor chips of different types are electrically connected to each other and operate as one system.

In some example embodiments, in the semiconductor package 10a according to some example embodiments, the first semiconductor chip 100 may be stacked on the package substrate 700. At this time, the first connection bump 140 may be formed on the package substrate 700, and the insulating adhesive layer 250 covering the first connection bump 140 may be formed. At this time, the first connection bump 140 may be electrically connected to the package substrate upper pad 720.

The insulating adhesive layer 250 may include, for example, a non-conductive film (NCF). The insulating adhesive layer 250 may be, for example, manufactured as a laminated film and attached to an upper surface of the package substrate 700. However, example embodiments of the method of forming the insulating adhesive layer 250 are not limited thereto, and the insulating adhesive layer 250 in a liquid state may, for example, be formed by using a spin coating method.

The insulating adhesive layer 250 may include a plurality of regions to be removed. the plurality of regions to be removed may refer to portions of the insulating adhesive layer 250 that overlap or at least partially overlap the corresponding plurality of first connection bumps 140 in the vertical direction. At this time, the vertical direction refers to a direction perpendicular to the upper surface of the package substrate 700.

Each of the plurality of regions to be removed may be formed to have a predetermined thickness in the vertical direction. A mask defining a plurality of openings corresponding to the plurality of regions to be removed may be formed on the insulating adhesive layer 250. The insulating adhesive layer 250 may be selectively removed by using the mask.

In more detail, the plurality of regions to be removed of the insulating adhesive layer 250 may be removed. A plurality of recessed units may be formed by removing at least a portion of the plurality of regions to be removed. The method of selectively removing the region to be removed of the insulating adhesive layer 250 by using the mask may be the same as described with reference to FIGS. 1 to 7. For example, the regions to be removed that are exposed through the openings defined by the mask may be selectively removed by, for example, using a laser drilling method and/or plasma.

Thereafter, the plurality of first lower connection pads 110 of the first semiconductor chip 100 may be aligned with the plurality of first connection bumps 140, respectively. By bonding the plurality of first lower connection pads 110 to the plurality of first connection bumps 140, the first semiconductor chip 100 may be electrically connected to the package substrate 700. Also, in a process of bonding the first semiconductor chip 100 on the package substrate 700, a thermal compression process, for example in which a predetermined amount of heat and pressure is applied to the insulating adhesive layer 250, may be performed. When predetermined amount of heat and pressure is applied to the insulating adhesive layer 250, a portion of the insulating adhesive layer 250 may move laterally.

An intermetallic compound 260 may be formed between the first connection bump 140 and the first lower connection pad 110 according to the thermal compression process. Also, the intermetallic compound 260 may be formed between the first connection bump 140 and the package substrate upper pad 720.

Thereafter, the plurality of second semiconductor chips 200 may be sequentially stacked on the first semiconductor chip 100. The insulating adhesive layer 250 may be formed between the first semiconductor chip 100 and the second semiconductor chip 200. Also, the insulating adhesive layer 250 may be formed between two adjacent second semiconductor chips 200. The process of forming the insulating adhesive layer 250 on the first semiconductor chip 100 and bonding the second semiconductor chip 200 on the insulating adhesive layer 250 may be the same as described above. Also, the process of forming the insulating adhesive layer 250 on the second semiconductor chip 200 and bonding the second semiconductor chip 200 on the insulating adhesive layer 250 may be the same as described above. For example, a plurality of regions to be removed of the insulating adhesive layer 250 may be selectively removed by using a mask. The plurality of second semiconductor chips 200 may be stacked by aligning with recessed units formed by removing a plurality of regions to be removed. Thereafter, a molding layer 800 may be formed on the first semiconductor chip 100 to cover or at least partially cover side surfaces of the plurality of second semiconductor chips 200.

While some inventive concepts have been particularly shown and described with reference to example embodiments thereof, it will be understood that various changes in form and details may be made therein without departing from the spirit and scope of the following claims.

Although example embodiments of inventive concepts have been described with reference to the accompanying drawings, it will be apparent to those ordinarily skilled in the art that inventive concepts may be realized in various forms without being limited to the above-described example embodiments and may be embodied in other specific forms without departing from the technical spirit and essential characteristics. Thus, the above example embodiments are to be considered in all respects as illustrative and neither limiting nor restrictive.

Terms, such as first, second, etc. may be used herein to describe various elements, but these elements should not be limited by these terms. The above terms are used only for the purpose of distinguishing one component from another. For example, a first element may be termed a second element, and, similarly, a second element may be termed a first element, without departing from the scope of the present disclosure.

Singular expressions may include plural expressions unless the context clearly indicates otherwise. Terms, such as “include” or “has” may be interpreted as adding features, numbers, steps, operations, components, parts, or combinations thereof described in the specification.

It will be understood that when an element or layer is referred to as being “on”, “connected to”, “coupled to”, “attached to”, or “in contact with” another element or layer, it can be directly on, connected to, coupled to, attached to, or in contact with the other element or layer, or intervening elements or layers may be present. In contrast, when an element is referred to as being “directly on”, “directly connected to”, “directly coupled to”, “directly attached to”, or “in direct contact with” another element or layer, there are no intervening elements or layers present. As used herein, the term “and/or” includes any and all combinations of one or more of the associated listed items.

When the terms “about” or “substantially” are used in this specification in connection with a numerical value, it is intended that the associated numerical value includes a manufacturing or operational tolerance (e.g., ±10%) around the stated numerical value. Moreover, when the words “generally” and “substantially” are used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes. When ranges are specified, the range includes all values therebetween such as increments of 0.1%.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

What is claimed is:

1. A method of manufacturing a semiconductor package, the method comprising:
preparing a first semiconductor chip, the first semiconductor chip including a plurality of first upper connection pads;
disposing a plurality of connection bumps on the first semiconductor chip, the connection bumps electrically connected to the plurality of first upper connection pads;
forming an insulating adhesive layer on an upper surface of the first semiconductor chip, the insulating adhesive layer at least partially covering the plurality of connection bumps;
removing a plurality of regions to be removed from the insulating adhesive layer; and
bonding a second semiconductor chip onto the insulating adhesive layer, the second semiconductor chip including a plurality of second lower connection pads,
wherein each of the plurality of regions to be removed is a portion of the insulating adhesive layer that at least partially overlaps a corresponding connection bump among the plurality of connection bumps in a vertical direction.

2. The method of claim 1, wherein
the removing of the plurality of regions to be removed includes
forming a mask on the insulating adhesive layer, the mask defining a plurality of openings individually corresponding to each of the plurality of regions to be removed; and
forming a plurality of recessed units by removing at least a portion of the plurality of regions to be removed that are exposed through the plurality of openings.

3. The method of claim 2, wherein the forming of the plurality of recessed units includes using a laser drilling method to remove at least a portion of the plurality of regions to be removed.

4. The method of claim 3, wherein the laser drilling method is performed in a line scan manner.

5. The method of claim 2, wherein the forming of the plurality of recessed units includes using plasma to remove at least a portion of the plurality of regions to be removed.

6. The method of claim 2, wherein the removing of the plurality of regions to be removed includes removing different amounts of the insulating adhesive layer from each of the plurality of regions to be removed.

7. The method of claim 1, wherein the removing of the plurality of regions to be removed includes removing each of the plurality of regions to be removed, and a thickness of each of plurality of the regions to be removed is in a range from 300 nm to 500 nm in the vertical direction.

8. The method of claim 1, wherein the removing of the plurality of regions to be removed includes exposing at least a portion of each of the plurality of connection bumps.

9. The method of claim 1, wherein
the bonding of the second semiconductor chip onto the insulating adhesive layer includes
aligning the plurality of second lower connection pads of the second semiconductor chip with the plurality of connection bumps, respectively; and
electrically connecting the second semiconductor chip to the first semiconductor chip.

10. The method of claim 9, wherein the electrically connecting of the second semiconductor chip to the first semiconductor chip includes using a thermal compression process.

11. The method of claim 1, wherein the forming of the insulating adhesive layer includes using a spin coating method or a laminating method.

12. A method of manufacturing a semiconductor package, the method comprising:
preparing a first semiconductor chip, the first semiconductor chip including a plurality of first upper connection pads;
disposing a plurality of connection bumps on the first semiconductor chip, the plurality of connection bumps electrically connected to the plurality of first upper connection pads;
forming an insulating adhesive layer on an upper surface of the first semiconductor chip, the insulating adhesive layer at least partially covering the plurality of connection bumps;
measuring thicknesses of a plurality of regions to be removed, the regions to be removed being portions of the insulating adhesive layer that at least partially overlap the plurality of connection bumps in a vertical direction;
forming a mask on the insulating adhesive layer, the mask including a plurality of openings corresponding to each of the plurality of regions to be removed;
removing the plurality of regions to be removed based on the measured thicknesses of the plurality of regions to be removed, the plurality of regions to be removed being exposed through the plurality of openings; and
bonding a second semiconductor chip onto the insulating adhesive layer, the second semiconductor chip including a plurality of second lower connection pads.

13. The method of claim 12, wherein the removing of the plurality of regions to be removed includes adjusting a removal amount of the insulating adhesive layer to be removed from each of the plurality of regions to be removed based on the measured thicknesses of the plurality of regions to be removed.

14. The method of claim 12, wherein the measuring of the thicknesses of the plurality of regions to be removed includes measuring a thickness distribution of the plurality of regions to be removed.

15. The method of claim 14, wherein the removing of the plurality of regions to be removed includes removing the plurality of regions to be removed in a vertical direction using maximum and minimum values of the thickness distribution.

16. The method of claim 12, wherein the removing of the plurality of regions to be removed includes exposing at least a portion of each of the plurality of connection bumps.

17. The method of claim 12, wherein the removing of the plurality of regions to be removed includes removing at least a portion of the plurality of regions to be removed using a laser drill method or plasma.

18. A method of manufacturing a semiconductor package, the method comprising:
preparing a package substrate;
stacking a plurality of semiconductor chips on the package substrate, each of the plurality of semiconductor chips including a plurality of upper connection pads and a plurality of lower connection pads; and
forming a molding layer on an upper surface of the package substrate, the molding layer at least partially covering the plurality of semiconductor chips,
wherein the stacking of the plurality of semiconductor chips includes
disposing a plurality of connection bumps, the plurality of connection bumps electrically connected to a plurality of upper connection pads of a semiconductor chip, the semiconductor chip located at a bottom of two adjacent semiconductor chips;
forming an insulating adhesive layer, the insulating adhesive layer configured to at least partially cover the plurality of connection bumps and including a plurality of regions to be removed, each of the plurality of regions to be removed at least partially overlapping ones of the plurality of connection bumps in a vertical direction;
forming a mask on the insulating adhesive layer, the mask defining a plurality of openings individually corresponding to the plurality of regions to be removed;
forming a plurality of recessed units by removing at least a portion of the plurality of regions to be removed, the regions to be removed being exposed through the plurality of openings; and
bonding the two adjacent semiconductor chips by aligning a plurality of lower connection pads of the uppermost semiconductor chip among the two adjacent semiconductor chips to correspond to the plurality of recessed units, respectively.

19. The method of claim 18, wherein the forming of the plurality of recessed units includes exposing at least a portion of each of the plurality of connection bumps.

20. The method of claim 18, wherein the forming of the plurality of recessed units includes removing at least a portion of the plurality of regions to be removed using a laser drill method or plasma.
